(19) United States
(12) Patent Application Publication
(10) Pub. No.: US 2006/0124930 A1
(43) Pub. Date: Jun. 15, 2006

(54) THIN FILM TRANSISTOR AND METHOD OF MAKING THE SAME

(76) Inventors: Chi-Wen Chen, Chia-Yi Hsien (TW); Ting-Chang Chang, Hsin-Chu City (TW); Po-Tsun Liu, Hsin-Chu City (TW); Feng-Yuan Gan, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/908,077

(22) Filed: Apr. 27, 2005

(30) Foreign Application Priority Data
Dec. 10, 2004 (TW) 093138503

(51) Int. Cl. H01L 31/0376; H01L 29/04

(52) U.S. Cl. 257/57; 257/59; 257/E51.005

(57) ABSTRACT

A thin film transistor is characterized by having an island-in structure having a semiconductor layer with a channel region, a bottom heavily-doped semiconductor layer, and a top heavily-doped semiconductor layer. The bottom heavily-doped semiconductor layer is positioned on two opposite sides of the surface of the semiconductor layer beyond the channel region. The top heavily-doped semiconductor layer, positioned on the bottom heavily-doped semiconductor layer, covers two opposite side walls of the bottom heavily-doped semiconductor layer and the semiconductor layer so that current leakage from the drain electrode to the source electrode is prevented.

This application claims the benefit of Taiwan application Serial No. 93138503, filed Dec. 10, 2004, the subject matter of which is incorporated herein by reference.

### BACKGROUND OF INVENTION

1. Field of the Invention

The present invention relates to a thin film transistor and method of making the same, and more particularly, to a thin film transistor capable of preventing source/drain current leakage and method of making the same.

2. Description of the Related Art

With the rapid development of Liquid Crystal Display (LCD) technologies, LCD panels have been widely applied to the display devices of various electronic products and flat televisions. An LCD panel is a passive type display device that requires a back light module as the light source, and therefore must be fabricated in a transparent substrate, such as a glass substrate. The glass substrate is not heat resistive, however, and thus amorphous silicon (a-Si:H), which has a lower process temperature range, is commonly adopted as the material of the semiconductor layer in thin film transistors of the LCD. The a-Si:H material is a well-known photoconductor and its conductivity increases drastically under illumination of a visible light. However, LCD panels are usually used in an illumination environment as well as under the backlight. Therefore, the leakage current of TFT under backlight illumination in TFT-LCD displays should be reduced to avoid losing the storage charges in the pixel.

Please refer to FIG. 1, which is a schematic diagram of a conventional light-shield amorphous silicon thin film transistor 10. As shown in FIG. 1, the amorphous silicon thin film transistor 10 includes a substrate 12, a gate electrode 14 positioned on the surface of the substrate 12, a gate insulating layer 16, which covers the gate electrode 14, positioned on the substrate 12, an amorphous silicon layer 18 positioned on the surface of the gate insulating layer 16, a heavily-doped amorphous silicon layer 20 positioned on two opposite sides of the surface of the amorphous silicon layer 18, and a source electrode 22 and a drain electrode 24 positioned on the heavily-doped amorphous silicon layer 20. The gate electrode 14, the source electrode 22, and the drain electrode 24 are made of metal materials. The amorphous silicon layer 18 includes a channel region 26. The amorphous silicon layer 18 and the heavily-doped amorphous silicon layer 20 are commonly referred to as an island structure. The function of the heavily-doped amorphous silicon layer 20 located on two opposite sides of the surface of the amorphous silicon layer 18 is to improve ohmic contact in the interface between the source electrode 22, the drain electrode 24, and the amorphous silicon layer 18. In addition, the conventional amorphous silicon thin film transistor 10 is an island-in structure, in which the dimension of the amorphous silicon layer 18 is smaller than the dimension of the gate electrode 14. Accordingly, the amorphous silicon thin film transistor 10 is unaffected by the back light source, and light-induced current leakage is prevented.

As shown in FIG. 1, the source electrode 22 and the drain electrode 24 are directly in contact with the side walls of the amorphous silicon layer 18. Because the source electrode 22 and the drain electrode 24 are made of metal materials, Schottky contact therefore occurs in an interface 28 of the source electrode 22, the drain electrode 24, and the amorphous silicon layer 18. In such a case, when a negative bias is applied to the gate electrode 12, holes gather towards the gate electrode 12. Meanwhile, if the drain electrode 24 is applied with a positive bias, the holes travel from the drain electrode 24 to the amorphous silicon layer 18 through the interface 28, and flow out from the source electrode 22. The hole flow therefore results in current leakage. Since the drain electrode 24 is electrically connected to a pixel electrode (not shown), the current leakage causes deviations in gray scales.

### SUMMARY OF INVENTION

It is therefore a primary object of the claimed invention to provide a thin film transistor and method of making the same to overcome the aforementioned problems.

According to the claimed invention, a thin film transistor and method of making the same are provided. The transistor includes a substrate; a gate electrode disposed on the substrate; a gate insulating layer, which covers the gate electrode, disposed on the substrate; an island structure disposed on the gate insulating layer; a source electrode; and a drain electrode. The island structure includes a semiconductor layer, which has a channel region, disposed on the gate insulating layer at a position corresponding to the gate electrode; and a top heavily-doped semiconductor layer, which covers at least one side wall or two opposite side walls of the semiconductor layer, disposed on the semiconductor layer. The source electrode and the drain electrode are disposed on the top heavily-doped semiconductor layer.

The method of making the thin film transistor includes the following steps:

providing a substrate;

forming a gate electrode on the substrate;

forming a gate insulating layer on the gate electrode;

forming a semiconductor layer on the gate insulating layer;

removing a portion of the semiconductor layer to make the remaining semiconductor layer entirely locate inside the gate electrode;

forming a top heavily-doped semiconductor layer on the gate insulating layer to cover at least one side wall of the semiconductor layer;

forming a conductive layer on the top heavily-doped semiconductor layer; and

removing a portion of the conductive layer and the top heavily-doped semiconductor layer to expose the semiconductor layer.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of a conventional light-shield amorphous thin film transistor.

FIG. 2 is a schematic diagram of an amorphous silicon thin film transistor according to a first preferred embodiment of the present invention.

FIG. 3 through FIG. 6 are schematic diagrams illustrating a method of forming the amorphous silicon thin film transistor shown in FIG. 2.

FIG. 7 is a schematic diagram of an amorphous silicon thin film transistor according to a second preferred embodiment of the present invention.

FIG. 8 through FIG. 12 are schematic diagrams illustrating a method of forming the amorphous silicon thin film transistor shown in FIG. 7.

FIG. 13 is a schematic diagram of an amorphous silicon thin film transistor according to a third preferred embodiment of the present invention.

FIG. 14 through FIG. 17 are schematic diagrams illustrating a method of forming the amorphous silicon thin film transistor shown in FIG. 13.

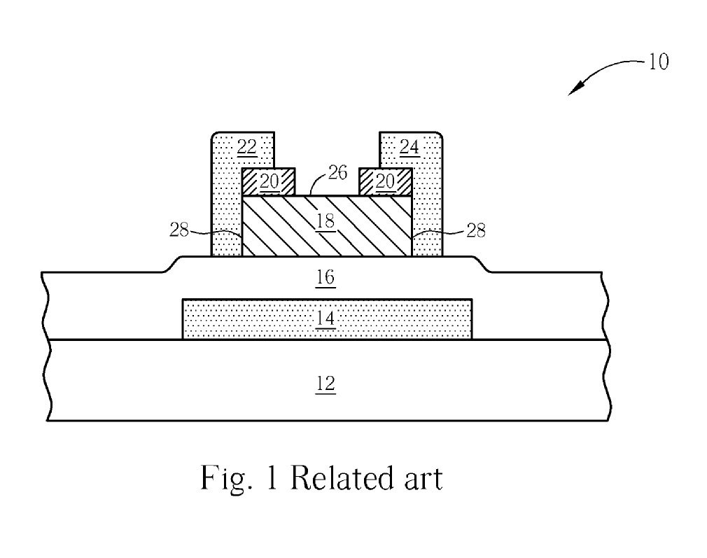

### DETAILED DESCRIPTION

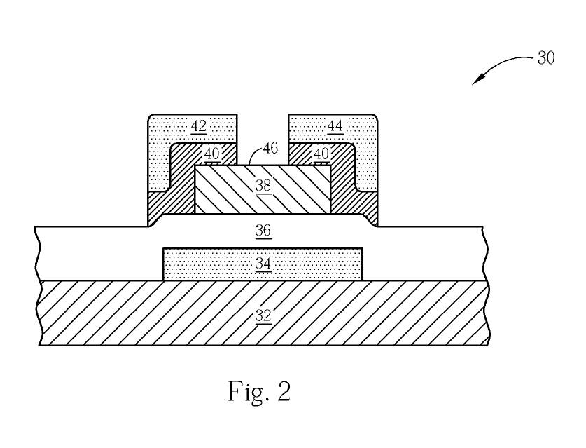

Please refer to FIG. 2, which is a schematic diagram of an amorphous silicon thin film transistor 30 according to a first preferred embodiment of the present invention. As shown in FIG. 2, the amorphous silicon thin film transistor 30 includes a substrate 32; a gate electrode 34 positioned on the substrate 32; a gate insulating layer 36, which covers the gate electrode 34, disposed on the substrate 32; an amorphous silicon layer 38 disposed on the gate insulating layer 36; a heavily-doped amorphous silicon layer 40 which covers two opposite sides of the surface and at least one side wall of the amorphous silicon layer 38, preferably, two opposite side walls of the amorphous silicon layer 38; and a source electrode 42 and a drain electrode 44 disposed on the heavily-doped amorphous silicon layer 40.

The substrate 32 is preferably, but not limited to, a glass substrate. The gate electrode 34, the source electrode 42, and the drain electrode 44 are made of metal or other conductive materials, such as aluminum or polysilicon. The amorphous silicon layer 38 and the heavily-doped amorphous silicon layer 40 can be replaced with other suitable semiconductor materials. The amorphous silicon layer 38 has a channel region 46, and the amorphous silicon layer 38 and the heavily-doped amorphous silicon layer 40 are commonly referred to as an island structure. In this embodiment, the dimension of the amorphous silicon layer 38 is smaller than the dimension of the gate electrode 34, thus the amorphous silicon thin film transistor 30 is, specifically, an island-in structure. By virtue of the island-in structure, the amorphous silicon thin film transistor 30 is unaffected by the back light source in operation, and therefore light-induced current leakage is prevented. The function of the heavily-doped amorphous silicon layer 40 is to improve ohmic contact in the interface between the source electrode 42, the drain electrode 44, and the amorphous silicon layer 38. Noteworthily, the heavily-doped amorphous silicon layer 40 not only covers two opposite sides of the surface of the amorphous silicon layer 38, but also covers the side walls of the amorphous silicon layer 38, so that the source electrode 42 and the drain electrode 44 are not directly in contact with the amorphous silicon layer 38. Therefore, Schotty contact does not occur. Accordingly, when the gate electrode 34 is applied with a negative bias, and the drain electrode 44 is applied with a positive bias, the current leakage between the source electrode 42 and the drain electrode 44 no longer occurs.

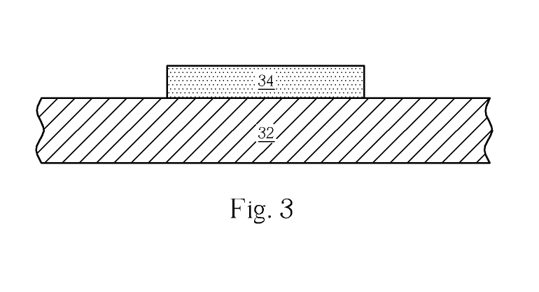

Please refer to FIG. 3 through FIG. 6. FIG. 3 through FIG. 6 are schematic diagrams illustrating a method of forming the amorphous silicon thin film transistor 30 shown in FIG. 2. As shown in FIG. 3, a substrate 32 is provided, and a gate electrode 34 is formed on the substrate 32. The substrate 32 can be a glass substrate, a quartz substrate, or other suitable substrate. The gate electrode 34 is made of conductive materials, such as metal or polysilicon, and is formed by lithographic techniques.

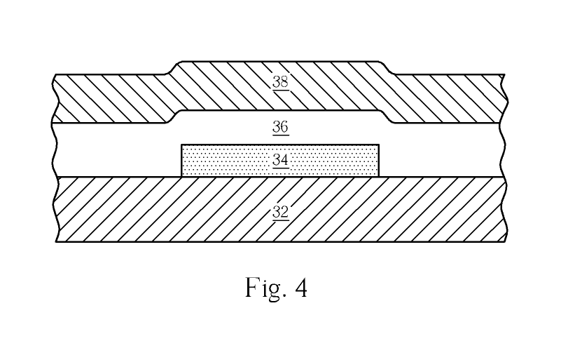

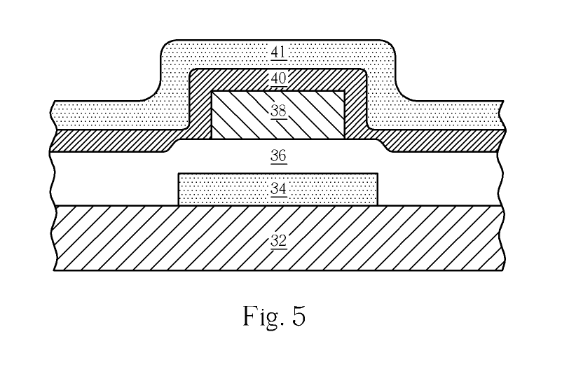

As shown in FIG. 4, a gate insulating layer 36 and an amorphous silicon layer 38 are consecutively formed on the substrate 32 and the gate electrode 34. The gate insulating layer 36, for example, is made of silicon oxide, silicon nitride, silicon oxynitride etc for insulating the gate electrode 34 and the amorphous silicon layer 38. As shown in FIG. 5, a lithography process is performed to remove a portion of the amorphous silicon layer 38, and only the amorphous silicon layer 38 disposed above the gate electrode 34 is preserved. The dimension of the amorphous silicon layer 38 is slightly smaller than the dimension of the gate electrode 34 so as to form an island-in structure. Subsequently, a heavily-doped amorphous silicon layer 40 and a metal layer 41 are formed on the amorphous silicon layer 38.

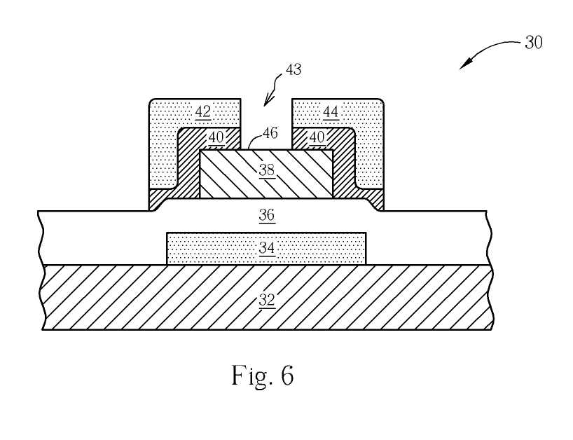

As shown in FIG. 6, another lithography process is performed using a masking pattern (not shown) to form an opening 43 in the metal layer 41, so as to respectively form a source electrode 42 and a drain electrode 44 on two opposite sides of the amorphous silicon layer 38. Subsequently, the heavily-doped amorphous silicon layer 40, which is not covered by the source electrode 42 and the drain electrode 44, is etched to accomplish the amorphous silicon thin film transistor 30. The amorphous silicon layer 38 corresponding to the opening 43 is a channel region 46. The step of removing the heavily-doped amorphous silicon layer 40 can be either implemented using the masking pattern for defining the source electrode 42 and the drain electrode 44, or the heavily-doped amorphous silicon layer 40 can also be etched using the source electrode 42 and the drain electrode 44 as a hard mask.

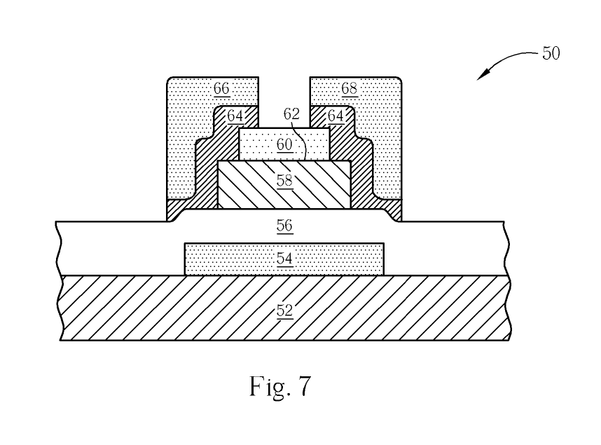

Please refer to FIG. 7, which is a schematic diagram of an amorphous silicon thin film transistor 50 according to a second preferred embodiment of the present invention. As shown in FIG. 7, the amorphous silicon thin film transistor 50 includes a substrate 52, a gate electrode 54 positioned on the substrate 52, a gate insulating layer 56, which covers the gate electrode 54, disposed on the substrate 52, an amorphous silicon layer 58 disposed on the gate insulating layer 56, an etching stop 60 disposed on a channel region 62 of the amorphous silicon layer 58, a heavily-doped amorphous silicon layer 64 which covers at least one side of the surface of the etching stop 60, preferably, covering two opposite sides of the surface of the etching stop 60 beyond the channel region 62, and at least one side wall of the amorphous silicon layer 58 and the etching stop 60, preferably, two opposite side walls of the amorphous silicon layer 58 and the etching stop 60, and a source electrode 66 and a drain electrode 68 disposed on the heavily-doped amorphous silicon layer 64.

The substrate 52 is preferably, but not limited to, a glass substrate. The gate electrode 54, the source electrode 66, and the drain electrode 68 are made of metal or other conductive materials, such as aluminum or polysilicon. The amorphous silicon layer 58 and the heavily-doped amorphous silicon layer 64 can be replaced with other suitable semiconductor materials. In this embodiment, the amorphous silicon thin film transistor 50 has an island-in structure. The function of the etching stop 60 is to prevent the amorphous silicon layer 58 from being damaged while patterning the heavily-doped amorphous silicon layer 64. The function of the heavily-doped amorphous silicon layer 64 is to improve ohmic contact in the interface between the source electrode 66, the drain electrode 68, and the amorphous silicon layer 58. The heavily-doped amorphous silicon layer 64 can partially cover the surface of the etching stop 60. Noteworthily, the heavily-doped amorphous silicon layer 64 not only covers two opposite sides of the surface of the amorphous silicon layer 58, but also covers the side walls of the amorphous silicon layer 58, so that the source electrode 66 and the drain electrode 68 are not directly in contact with the amorphous silicon layer 58. Therefore, Schotty contact does not occur. Accordingly, when the gate electrode 54 is applied with a negative bias, and the drain electrode 68 is applied with a positive bias, the current leakage between the source electrode 66 and the drain electrode 68 no longer occurs.

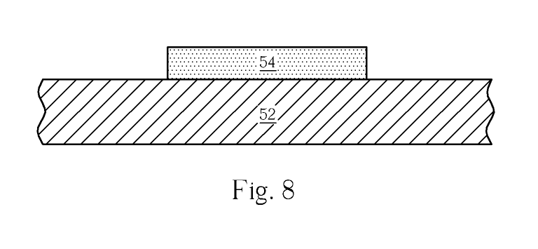

Please refer to FIG. 8 through FIG. 12. FIG. 8 through FIG. 12 are schematic diagrams illustrating a method of forming the amorphous silicon thin film transistor 50 shown in FIG. 7. As shown in FIG. 8, a substrate 52 is provided, and a gate electrode 54 is formed on the substrate 52. The substrate 52 can be a glass substrate, a quartz substrate, or other suitable substrate. The gate electrode 54 is made of conductive materials, such as metal or polysilicon, and can be formed by lithographic techniques.

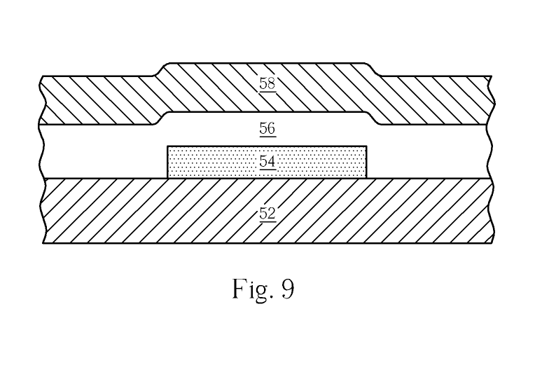

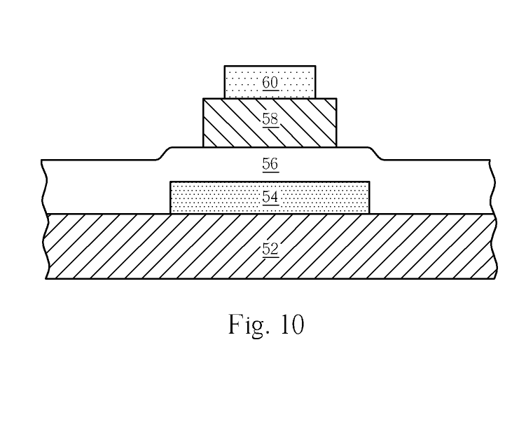

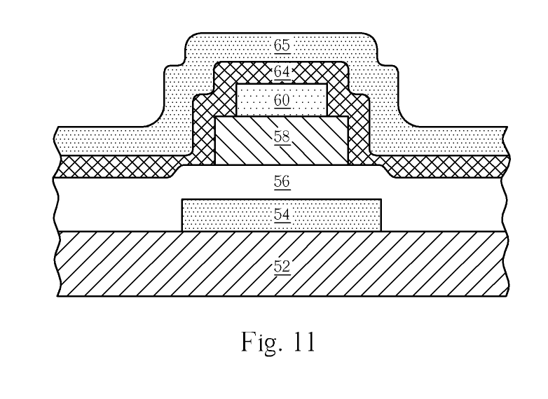

As shown in FIG. 9, a gate insulating layer 56 and an amorphous silicon layer 58 are consecutively formed on the substrate 52 and the gate electrode 54. The gate insulating layer 56, for example, is made of silicon oxide, silicon nitride, silicon oxynitride, etc for insulating the gate electrode 54 and the amorphous silicon layer 58. As shown in FIG. 10, a lithography process is performed to remove a portion of the amorphous silicon layer 58, and only the amorphous silicon layer 58 disposed above the gate electrode 54 is preserved. The dimension of the amorphous silicon layer 58 is slightly smaller than the dimension of the gate electrode 54 so as to form an island-in structure. Subsequently, an etching stop 60 is formed on the amorphous silicon layer 58 to protect the amorphous silicon layer 58. As shown in FIG. 11, a heavily-doped amorphous silicon layer 64 and a metal layer 65 are consecutively formed on the surface of the gate insulating layer 56, the amorphous silicon layer 58, and the etching stop 60.

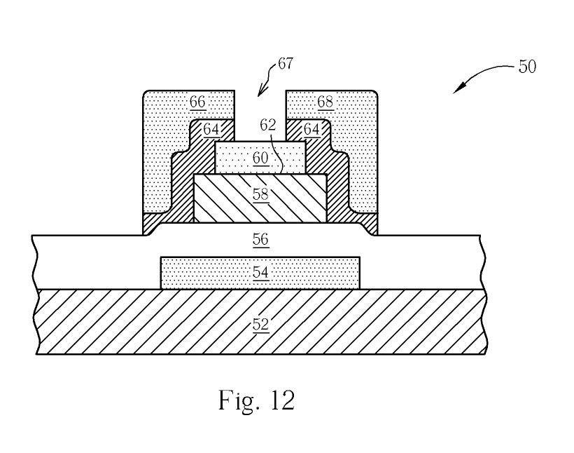

As shown in FIG. 12, another lithography process is performed using a masking pattern (not shown) to form an opening 67 in the metal layer 65, so as to respectively form a source electrode 66 and a drain electrode 68 on two opposite sides of the amorphous silicon layer 58. Subsequently, the heavily-doped amorphous silicon layer 64, which is not covered by the source electrode 66 and the drain electrode 68, is etched to accomplish the amorphous silicon thin film transistor 50. The amorphous silicon layer 58 corresponding to the opening 67 is a channel region 62. The step of removing the heavily-doped amorphous silicon layer 64 can be either implemented using the masking pattern for defining the source drain 66 and the drain electrode 68, or the heavily-doped amorphous silicon layer 64 can also be etched using the source electrode 66 and the drain electrode 68 as a hard mask.

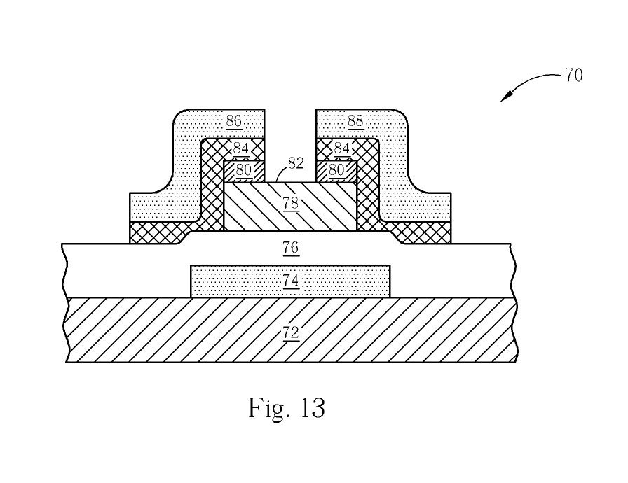

Please refer to FIG. 13, which is a schematic diagram of an amorphous silicon thin film transistor 70 according to a third preferred embodiment of the present invention. As shown in FIG. 13, the amorphous silicon thin film transistor 70 includes a substrate 72; a gate electrode 74 disposed on the substrate 72; a gate insulating layer 76, which covers the gate electrode 74, disposed on the substrate 72; an amorphous silicon layer 78 positioned on the gate insulating layer 76; a bottom heavily-doped amorphous silicon layer 80 which covers two opposite sides of the surface of the amorphous silicon layer 78 beyond a channel region 82 of the amorphous silicon layer 78; a top heavily-doped amorphous silicon layer 84 which covers the top surface of the bottom heavily-doped amorphous silicon layer 80, and at least one side wall of the bottom heavily-doped amorphous layer 80 and the amorphous silicon layer 78, preferably, two opposite side walls of the bottom heavily-doped amorphous layer 80 and the amorphous silicon layer 78; and a source electrode 86 and a drain electrode 88 disposed on the top heavily-doped amorphous silicon layer 84.

The substrate 72 is preferably, but not limited to, a glass substrate. The gate electrode 74, the source electrode 86, and the drain electrode 88 are made of metal or other conductive materials, such as aluminum or polysilicon. The amorphous silicon layer 78, the bottom heavily-doped amorphous silicon layer 80, and the top heavily-doped amorphous silicon layer 84 form an island-in structure. The function of the bottom heavily-doped amorphous silicon layer 80 and the top heavily-doped amorphous silicon layer 84 is to improve ohmic contact in the interface between the source electrode 86, the drain electrode 88, and the amorphous silicon layer 78. In this embodiment, the amorphous silicon thin film transistor 70 has two heavily-doped amorphous silicon layers including the bottom heavily-doped amorphous silicon layer 80 and the top heavily-doped amorphous silicon layer 84. This is because the bottom heavily-doped amorphous silicon layer 80 is defined by a photoresist pattern, and the surface condition is deteriorated due to particles or other factors. On the other hand, the top heavily-doped amorphous silicon layer 84 is defined by the source electrode 86 and the drain electrode 88 lain thereon, and thus the surface condition of the top heavily-doped amorphous silicon layer 84 is better.

In addition, the top heavily-doped amorphous silicon layer 84 covers the side walls of the bottom heavily-doped amorphous silicon layer 80 and the amorphous silicon layer 78, so that the source electrode 86 and the drain electrode 88 are not directly in contact with the amorphous silicon layer 78. Therefore, Schotty contact does not occur. Accordingly, when the gate electrode 74 is applied with a negative bias, and the drain electrode 88 is applied with a positive bias, the current leakage between the source electrode 86 and the drain electrode 88 no longer occurs.

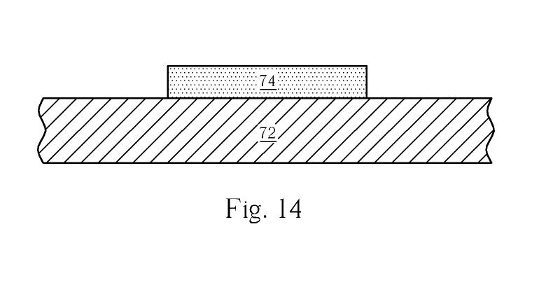

Please refer to FIG. 14 through FIG. 17. FIG. 14 through FIG. 17 are schematic diagrams illustrating a method of forming the amorphous silicon thin film transistor 70 shown in FIG. 13. As shown in FIG. 14, a substrate 72 is provided, and a gate electrode 74 is formed on the substrate 72. The substrate 72 can be a glass substrate, a quartz substrate, or other suitable substrate. The gate electrode 74 is made of conductive materials, such as metal or polysilicon, and is formed by lithographic techniques.

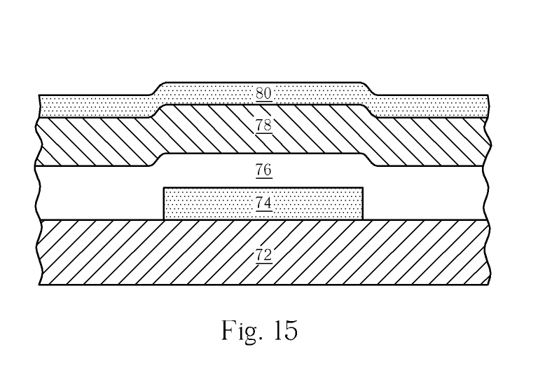

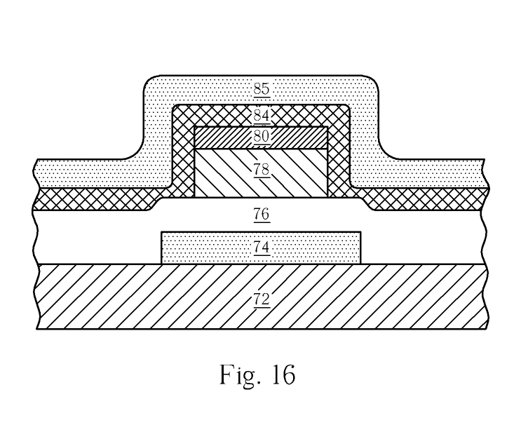

As shown in FIG. 15, a gate insulating layer 76, an amorphous silicon layer 78, and a bottom heavily-doped amorphous silicon layer 80 are consecutively formed on the substrate 72 and the gate electrode 74. The gate insulating layer 76, for example, is made of silicon oxide, silicon nitride, silicon oxynitride, etc for insulating the gate electrode 74 and the amorphous silicon layer 78. As shown in FIG. 16, a lithography process is performed to remove a portion of the bottom heavily-doped amorphous silicon layer 80 and the amorphous silicon layer 78, and only the bottom heavily-doped amorphous silicon layer 80 and the amorphous silicon layer 78 disposed over the gate electrode 74 is preserved. The dimension of the amorphous silicon layer 78 is slightly smaller than the dimension of the gate electrode 74 so as to form an island-in structure. Subsequently, a top heavily-doped amorphous silicon layer 84 and a metal layer 85 are consecutively formed on the surface of the gate insulating layer 76 and the bottom heavily-doped amorphous silicon layer 80.

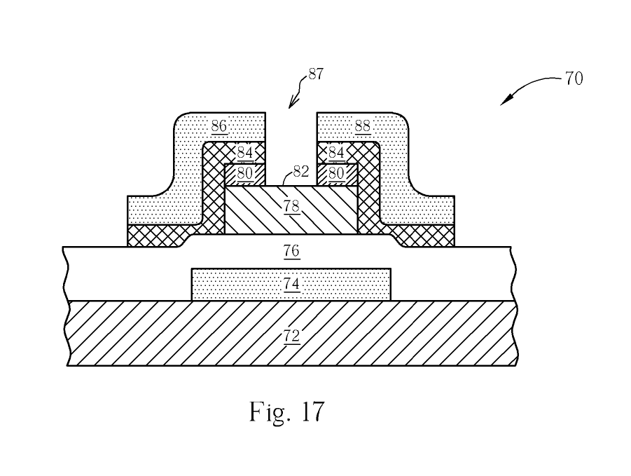

As shown in FIG. 17, another lithography process is performed using a masking pattern (not shown) to form an opening 87 in the metal layer 85, so as to respectively form a source electrode 86 and a drain electrode 88 on two opposite sides of the amorphous silicon layer 78. Subsequently, the top heavily-doped amorphous silicon layer 84 and the bottom heavily-doped amorphous silicon layer 80, which are not covered by the source electrode 86 and the drain electrode 88, are etched to accomplish the amorphous silicon thin film transistor 70. The amorphous silicon layer 78 corresponding to the opening 87 is a channel region 82. The step of removing the top heavily-doped amorphous silicon layer 84 and the bottom heavily-doped amorphous silicon layer 80 to expose the semiconductor layer can be either implemented using the masking pattern for defining the source electrode 86 and the drain electrode 88, or the top heavily-doped amorphous silicon layer 84 and the bottom heavily-doped amorphous silicon layer 80 can also be etched by using the source electrode 86 and the drain electrode 88 as a hard mask.

The above embodiments utilize an amorphous silicon thin film transistor and method of making the same to illustrate the features of the present invention. This is because Schottky contact tends to occur in the interface of the metal electrode and the amorphous silicon layer. However, the application of the present invention is not limited. If Schottky contact occurs in the interface of the semiconductor layer made of other materials and the metal electrode, the present invention is also applicable to reduce the current leakage problem.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A thin film transistor, comprising:
a substrate;
a gate electrode disposed on the substrate;
a gate insulating layer disposed on the substrate to cover the gate electrode;
an island structure, disposed on the gate insulating layer, comprising:
a semiconductor layer, disposed on the gate insulating layer corresponding to the gate electrode, having a channel region; and
a top heavily-doped semiconductor layer disposed on the semiconductor layer to cover at least one side wall of the semiconductor layer; and
a source electrode and a drain electrode disposed on the top heavily-doped semiconductor layer, respectively.

2. The thin film transistor of claim 1, wherein the dimension of the semiconductor layer is smaller than the dimension of the gate electrode.

3. The thin film transistor of claim 1, wherein the top heavily-doped semiconductor layer covers two opposite side walls of the semiconductor layer.

4. The thin film transistor of claim 1, wherein the semiconductor layer comprises an amorphous silicon layer.

5. The thin film transistor of claim 1, wherein the top heavily-doped semiconductor layer comprises a heavily-doped amorphous silicon layer.

6. The thin film transistor of claim 1, wherein the island structure further comprises an etching stop disposed between the semiconductor layer and the top heavily-doped semiconductor layer.

7. The thin film transistor of claim 6, wherein the top heavily-doped semiconductor layer covers at least one side wall of the etching stop.

8. The thin film transistor of claim 7, wherein the top heavily-doped semiconductor layer covers two opposite side walls of the etching stop.

9. The thin film transistor of claim 1, wherein the island structure further comprises a bottom heavily-doped semiconductor layer disposed between the semiconductor layer and the top heavily-doped semiconductor layer, and the bottom heavily-doped semiconductor layer corresponds to two opposite sides of the channel region.

10. The thin film transistor of claim 9, wherein the top heavily-doped semiconductor layer covers at least one side wall of the bottom heavily-doped semiconductor layer and at least one side wall of the semiconductor layer.

11. The thin film transistor of claim 10, wherein the top heavily-doped semiconductor layer covers two opposite side walls of the bottom heavily-doped semiconductor layer and two opposite side walls of the semiconductor layer.

12. A method for fabricating a thin film transistor, comprising:
providing a substrate;
forming a gate electrode on the substrate;
forming a gate insulating layer on the gate electrode;
forming a semiconductor layer on the gate insulating layer;
removing a portion of the semiconductor layer to make the remaining semiconductor layer correspond to the gate electrode;
forming a top heavily-doped semiconductor layer on the gate insulating layer to cover at least one side wall of the semiconductor layer;
forming a conductive layer on the top heavily-doped semiconductor layer; and
removing a portion of the conductive layer and the top heavily-doped semiconductor layer to expose the semiconductor layer.

13. The method of claim 12, further comprising forming an etching stop on the semiconductor layer prior to forming the top heavily-doped semiconductor layer.

14. The method of claim 13, wherein the step of forming the top heavily-doped semiconductor layer on the gate insulating layer comprises:
forming the top heavily-doped semiconductor layer on the gate insulating layer to cover the upper surface, at least one side wall of the etching stop, and at least one side wall of the semiconductor layer.

15. The method of claim 13, wherein the step of removing the portion of the conductive layer and the top heavily-doped semiconductor layer comprises:
removing the conductive layer disposed over the central portion of the semiconductor layer to form a source electrode and a drain electrode over two opposite sides of the semiconductor layer; and
removing the top heavily-doped semiconductor layer, not covered by the source electrode and the drain electrode, to expose the semiconductor layer.

16. The method of claim 13, wherein the step of removing the portion of the conductive layer and the top heavily-doped semiconductor layer comprises:
masking the conductive layer to cover two opposite sides of the conductive layer; and
removing the conductive layer and the top heavily-doped semiconductor layer not masked to expose the semiconductor layer.

17. The method of claim 12, further comprising:
forming a bottom heavily-doped semiconductor layer on the semiconductor layer; and
removing a portion of the bottom heavily-doped semiconductor layer to make the bottom heavily-doped semiconductor layer correspond to the gate electrode.

18. The method of claim 17, wherein the step of forming the top heavily-doped semiconductor layer on the gate insulating layer comprises:
forming the top heavily-doped semiconductor layer on the gate insulating layer to cover the upper surface and at least one side wall of the bottom heavily-doped semiconductor layer, and at least one side wall of the semiconductor layer.

19. The method of claim 17, wherein the step of removing the portion of the conductive layer and the top heavily-doped semiconductor comprises:
removing the conductive layer disposed over the central portion of the semiconductor layer to form a source electrode and a drain electrode over two opposite sides of the semiconductor layer;
removing the top heavily-doped semiconductor layer, not covered by the source electrode and the drain electrode, to expose the bottom heavily-doped semiconductor layer; and
removing the bottom heavily-doped semiconductor layer, not covered by the top heavily-doped semiconductor layer, to expose the semiconductor layer.

20. The method of claim 17, wherein the step of removing the portion of the conductive layer and the top heavily-doped semiconductor layer comprises:
masking the conductive layer to cover two opposite sides of the conductive layer; and
removing the conductive layer, the top heavily-doped semiconductor layer, and the bottom heavily-doped semiconductor layer not masked to expose the semiconductor layer.

21. The method of claim 12, wherein the step of removing the portion of the conductive layer and the top heavily-doped semiconductor layer comprises:
removing the conductive layer disposed over the central portion of the semiconductor layer to form a source electrode and a drain electrode over two opposite sides of the semiconductor layer; and
removing the top heavily-doped semiconductor layer not covered by the source electrode and the drain electrode to expose the semiconductor layer.

22. The method of claim 12, wherein the step of removing the portion of the conductive layer and the top heavily-doped semiconductor layer comprises:
masking the conductive layer to cover two opposite sides of the conductive layer; and
removing the conductive layer and the top heavily-doped semiconductor layer not masked to expose the semiconductor layer.
